(19) United States
(12) Patent Application Publication
(10) Pub. No.: US 2024/0113213 A1
(43) Pub. Date: Apr. 4, 2024

(54) HYBRID INSERTED DIELECRIC GATE-ALL-AROUND DEVICE

(71) Applicant: INTERNATIONAL BUSINESS MACHINES CORPORATION, Armonk, NY (US)

(72) Inventors: Julien Frougier, Albany, NY (US); Ruilong Xie, Niskayuna, NY (US); Kangguo Cheng, Schenectady, NY (US); Andrew M. Greene, Slingerlands, NY (US); Sung Dae Suk, Watervliet, NY (US)

(21) Appl. No.: 17/957,194

(22) Filed: Sep. 30, 2022

(51) Int. Cl. H01L 29/775; H01L 29/06; H01L 29/423; H01L 29/66

(52) U.S. Cl. CPC H01L 29/775; H01L 29/0673; H01L 29/42392; H01L 29/66439; H01L 29/66545

(57) ABSTRACT

A semiconductor device including a channel region of stacked semiconductor layers arranged in at least one cluster, wherein each cluster includes a pair of the semiconductor sheets with a dielectric material present therebetween. The semiconductor device further includes a gate structure encapsulating the channel region of stacked semiconductor sheets arranged in clusters. Source and drain regions are present on opposing sides of the channel region.

### BACKGROUND

The present disclosure relates to semiconductor devices, and more particularly to gate all around devices.

Continued innovations in semiconductor process technologies are enabling higher integration densities and device scaling. The well-known field-effect transistor (FET) is a device that uses an electric field to control the flow of current in a semiconductor, and typically includes source, gate, drain (and body) terminals. FET devices control the flow of current by the application of a voltage to the gate, which in turn alters the conductivity in the channel between the drain and source. The fin-type field effect transistor (FinFET) is a multi-gate device, built on a substrate, with the gate placed on two or more sides of the channel or wrapped around the channel, thus forming a multiple-gate structure. FinFET devices have significantly faster switching times and higher current density than planar CMOS (complementary metal-oxide-semiconductor) FET technology.

Further advances beyond FinFETs have been proposed in the form of vertically-stacked semiconductor nanowires channels employed as metal-oxide-semiconductor field-effect transistor (MOSFET) channels which can enable a gate-surrounding structure allowing good electrostatic gate control over the channel for reducing short-channel effects. Similar to lateral nanowire FETs, Gate-All-Around (GAA) Nanosheet FETs use wider and thicker wires to provide improved electrostatics and drive current.

### SUMMARY

In one aspect, the present disclosure provides a hybrid inserted dielectric, e.g., inserted oxide, gate all around (GAA) device with channel clusters.

In one embodiment, a semiconductor device is provided including at least one pair of stacked semiconductor sheets for channel regions. Each of the at least one pair of stacked semiconductor sheets has an inserted dielectric present between the semiconductor sheets, wherein the inserted dielectric does not extend to an edge of semiconductor sheets. A gate structure is provided encapsulating each of the at least one pair of stacked semiconductor sheets, wherein the gate structure is in directed contact with a lower surface of the a lower semiconductor sheet in the at least one pair of stacked semiconductor sheets, and is in direct contact with an upper surface of an upper semiconductor sheet in the at least one pair of stacked semiconductor sheets.

In another embodiment, a hybrid inserted dielectric gate all around (GAA) device is provided with channel clusters, in which the inserted dielectric may be provided by a gate dielectric that is deposited to fill the space between at least one pair of stacked semiconductor layers that provide the channel region, while the dielectric material of the gate dielectric does not fill the space separating pairs of stacked semiconductor layers. In one embodiment, a semiconductor device is provided including at least one pair of stacked semiconductor sheets for channel regions. The at least one pair of stacked semiconductor sheets has the space between them filled with a dielectric material of the gate dielectric for a gate structure to the device. The gate structure is provided encapsulating the at least one pair of stacked semiconductor sheets.

In yet another embodiment, a semiconductor device is provided including a channel region of stacked semiconductor layers arranged in clusters, wherein each cluster includes a pair of the semiconductor sheets with a dielectric material present therebetween. The semiconductor device further includes a gate structure encapsulating the channel region of stacked semiconductor sheets arranged in clusters, wherein a portion of the gate structure is present between the clusters. Source and drain regions are present on opposing sides of the channel region.

In another aspect a method of forming a hybrid inserted dielectric gate all around (GAA) device with channel clusters is provided. In one embodiment, the method includes providing a material stack on a supporting substrate including a first composition of semiconductor layers for semiconductor sheets employed for channel regions, second composition semiconductor layers for a replacement gate process, and third composition semiconductor layers for positioning inserted dielectrics between two of said semiconductor sheets in a channel cluster. The method may continue with forming a sacrificial gate structure on the material stack. An inserted dielectric may then be substituted for the third composition semiconductor layers. Source and drain epitaxial regions may be formed on opposing sides of the channel region. The sacrificial gate structure and the second composition semiconductor layers are removed, wherein removing the second composition semiconductor layers exposes at least one channel cluster each including two semiconductor sheets having an inserted dielectric present therebetween. A functional gate structure is formed on the at least one channel cluster, wherein the functional gate structure encapsulates an entirety of each of the at least one channel cluster.

In another embodiment, method of forming a hybrid inserted dielectric gate all around (GAA) device including at least one channel cluster is provided, in which the inserted dielectric may be provided by a gate dielectric that is deposited to fill the space between at least one pair of the stacked semiconductor layers that provides the channel region. In one embodiment, the method includes providing a material stack on a supporting substrate including a first composition of semiconductor layers for semiconductor sheets employed for channel regions, and a second composition semiconductor layers for a replacement gate process and for positioning inserted dielectrics between two of said semiconductor sheets in a channel cluster. The method may continue with forming a sacrificial gate structure on the material stack. Source and drain epitaxial regions may be formed on opposing sides of the channel region. The sacrificial gate structure and the second composition semiconductor layers are removed, wherein removing the second composition semiconductor layers exposes at least one channel cluster including two semiconductor sheets having an a space for inserted dielectric present therebetween. The gate dielectric of a functional gate structure is formed on the at least one channel cluster, wherein the functional gate dielectric encapsulates an entirety of each of the at least one channel cluster and fills the space separating the at least two semiconductor sheets for the at least one channel cluster. A gate electrode is formed on the gate dielectric.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a top down view illustrating hybrid inserted dielectric gate all around devices with channel clusters.

FIG. 2 is a side cross-sectional view along section line X-X of FIG. 1 illustrating an embodiment, in which channel clusters include stacked semiconductor sheets for channel regions, wherein each of the stacked semiconductor sheets has an inserted dielectric present between the semiconductor sheets, in accordance with one embodiment of the present disclosure.

FIG. 3 is a side cross-sectional view along section line Y-Y of FIG. 1 illustrating an embodiment, in which the channel clusters include stacked semiconductor sheets for channel regions having an inserted dielectric between the stacked sheets for each cluster, wherein the inserted dielectric does not extend to an edge of semiconductor sheets, in accordance with one embodiment of the present disclosure.

FIG. 4 is a side cross-sectional view along section line Z-Z of FIG. 1 illustrating an embodiment of the source and drain epitaxial regions of a device including channel clusters, in which the clusters include stacked semiconductor sheets for channel regions having an inserted dielectric between the stacked sheets for each cluster, in accordance with one embodiment of the present disclosure.

FIG. 5 is a side cross-sectional view along section line X-X of FIG. 1 illustrating another embodiment, in which a semiconductor device is provided including at least one pair of stacked semiconductor sheets for channel regions, and each of the at least one pair of stacked semiconductor sheets has the space between them filled with a dielectric material of a gate dielectric that provides an inserted dielectric layer of a channel cluster.

FIG. 6 is a side cross-sectional view along section line Y-Y of FIG. 1 illustrating another embodiment, in which a semiconductor device is provided including at least one pair of stacked semiconductor sheets for channel regions, and each of the at least one pair of stacked semiconductor sheets has the space between them filled with a dielectric material of a gate dielectric that provides an inserted dielectric layer of a channel cluster.

FIG. 7 is a side cross-sectional view along section line Z-Z of FIG. 1 illustrating the source and drain epitaxial regions of a semiconductor device including at least one pair of stacked semiconductor sheets for channel regions, in which each of the at least one pair of stacked semiconductor sheets has the space between them filled with a dielectric material of a gate dielectric that provides an inserted dielectric layer of a channel cluster.

FIG. 8 is a side cross-sectional view illustrating one embodiment of a material stack of epitaxially grown semiconductor materials that can be used as the initial structure for a process for forming the device depicted in FIGS. 1-4.

FIG. 9 is a side cross-sectional view illustrating one embodiment of forming nanosheet stack structures from the stack illustrated in FIG. 8.

FIG. 10 is a side cross-sectional view along section line X-X of FIG. 1 illustrating one embodiment of forming a sacrificial gate structure on the nanosheet stack structures depicted in FIG. 9, and removing the third composition semiconductor layer, in accordance with one embodiment of the present disclosure.

FIG. 11 is a side cross-sectional view along section line Y-Y of FIG. 1 illustrating one embodiment of forming a sacrificial gate structure on the nanosheet stack structures depicted in FIG. 9, and removing the third composition semiconductor layer, in accordance with one embodiment of the present disclosure.

FIG. 12 is a side cross-sectional view along section line Z-Z of FIG. 1 illustrating one embodiment of forming a sacrificial gate structure on the nanosheet stack structures depicted in FIG. 9, and removing the third composition semiconductor layer, in accordance with one embodiment of the present disclosure.

FIG. 13 is a side cross-sectional view along illustrate one embodiment of forming the inserted dielectric layer in the opening formed by removing third composition semiconductor layer, as depicted in FIG. 10.

FIG. 14 is a side cross-sectional view along illustrate one embodiment of forming the inserted dielectric layer in the opening formed by removing third composition semiconductor layer, as depicted in FIG. 11.

FIG. 15 is a side cross-sectional view along illustrate one embodiment of forming the inserted dielectric layer in the opening formed by removing third composition semiconductor layer, as depicted in FIG. 11.

FIG. 16 is a side cross-sectional view of recessing the nanosheet stack structures along the section line depicted in FIG. 13.

FIG. 17 is a side cross-sectional view of recessing the nanosheet stack structures along the section line depicted in FIG. 14.

FIG. 18 is a side cross-sectional view that illustrates recessing the nanosheet stack structures along the section line depicted in FIG. 15.

FIG. 19 depicts one embodiment of removing the sacrificial gate structure and removing the third composition semiconductor layer along the section depicted in FIG. 16.

FIG. 20 depicts one embodiment of removing the sacrificial gate structure and removing the third composition semiconductor layer along the section depicted in FIG. 17.

FIG. 21 is a side cross-sectional view illustrating one embodiment of a material stack of epitaxially grown semiconductor materials that can be used as the initial structure for a process for forming the device depicted in FIGS. 1 and 5-7.

FIG. 22 is a side cross-sectional view along section line X-X of FIG. 1 illustrating one embodiment of forming a sacrificial gate structure on the nanosheet stack structures formed from the stack depicted in FIG. 21, and removing the sacrificial semiconductor layer for forming the bottom dielectric isolation layer, in accordance with one embodiment of the present disclosure.

FIG. 23 is a side cross-sectional view along section line Y-Y of FIG. 1 illustrating one embodiment of forming a sacrificial gate structure on the nanosheet stack structures formed from the stack depicted in FIG. 21, and removing the sacrificial semiconductor layer for forming the bottom dielectric isolation layer, in accordance with one embodiment of the present disclosure.

FIG. 24 is a side cross-sectional view along section line Z-Z of FIG. 1 illustrating one embodiment of forming a sacrificial gate structure on the nanosheet stack structures formed from the stack depicted in FIG. 21, and removing the sacrificial semiconductor layer for forming the bottom dielectric isolation layer, in accordance with one embodiment of the present disclosure.

FIG. 25 is a side cross-sectional view illustrating one embodiment of forming the bottom dielectric isolation layer simultaneously with gate sidewall spacers on the sacrificial gate structure for the cross-sectional view depicted in FIG. 22.

FIG. 26 is a side cross-sectional view illustrating one embodiment of forming the bottom dielectric isolation layer simultaneously with gate sidewall spacers on the sacrificial gate structure depicted in the cross-sectional view illustrated in FIG. 23.

FIG. 27 is a side cross-sectional view illustrating one embodiment of forming the bottom dielectric isolation layer simultaneously with gate sidewall spacers on the sacrificial gate structure depicted in the cross-sectional view illustrated in FIG. 24.

FIG. 28 is a side cross-sectional view illustrating one embodiment of a nanosheet stack recess step, the formation of an inner spacer and source/drain epitaxy formation that is applied to the structure having the cross-sectional view depicted in FIG. 25.

FIG. 29 is a side cross-sectional view illustrating one embodiment of the nanosheet stack recess step, the formation of an inner spacer and source/drain epitaxy formation that is applied to the structure having the cross-sectional view depicted in FIG. 26.

FIG. 30 is a side cross-sectional view illustrating one embodiment of the nanosheet stack recess step, the formation of an inner spacer and source/drain epitaxy formation that is applied to the structure having the cross-sectional view depicted in FIG. 29.

FIG. 31 is a side cross-sectional view illustrating one embodiment of removing the sacrificial gate structure and sacrificial layers in the channel region as applied to the structure depicted by the cross-sectional view in FIG. 28.

FIG. 32 is a side cross-sectional view illustrating one embodiment of removing the sacrificial gate structure and sacrificial layers in the channel region as applied to the structure depicted by the cross-sectional view in FIG. 28.

FIG. 33 is a side cross-sectional view depicting forming the gate dielectric of the functional gate structure, in which the gate dielectric fills the space between adjacently stacked semiconductor sheets in at least one channel cluster, as applied to the structure depicted by the cross-sectional view in FIG. 31.

FIG. 34 is a side cross-sectional view depicting forming the gate dielectric of the functional gate structure, in which the gate dielectric fills the space between adjacently stacked semiconductor sheets in at least one channel cluster, as applied to the structure depicted by the cross-sectional view in FIG. 32.

### DETAILED DESCRIPTION OF PREFERRED EMBODIMENTS

Detailed embodiments of the claimed methods, structures and computer products are disclosed herein; however, it is to be understood that the disclosed embodiments are merely illustrative of the claimed structures and methods that may be embodied in various forms. In addition, each of the examples given in connection with the various embodiments is intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. For purposes of the description hereinafter, the terms “upper”, “over”, “overlying”, “lower”, “under”, “underlying”, “right”, “left”, “vertical”, “horizontal”, “top”, “bottom”, and derivatives thereof shall relate to the embodiments of the disclosure, as it is oriented in the drawing figures. The term “positioned on” means that a first element, such as a first structure, is present on a second element, such as a second structure, wherein intervening elements, such as an interface structure, e.g. interface layer, may be present between the first element and the second element. The term “direct contact” means that a first element, such as a first structure, and a second element, such as a second structure, are connected without any intermediary conducting, insulating or semiconductor layers at the interface of the two elements.

It has been determined that development of advanced technology nodes including, Gate-All-Around devices, is governed by the co-optimization of the effective drive current (Ieff) representing the raw performance of the device and the effective parasitic capacitance (Ceff) representing the delay of the device and circuit. The overarching goal for every technology node is to maximize device performance while minimizing circuit delay for a given footprint. For example, to maximize the effective drive current (Ieff), the effective width (Weff) of the device can be increased. On the other hand, reducing parasitic capacitance (Ceff) and circuit delay can be achieved by using dielectric materials with lower dielectric constants (low-k materials) and by reducing the total surface of the parasitic capacitors formed in the device and circuit. Additionally, there is a need to maintain or improve electrostatic control over the channel to mitigate short channel effects (SCE) as the critical gate dimensions of the devices keep scaling.

Inserted-oxide Fin Field Effect Transistors (i-FinFETs) position a piece of oxide between the floating channels of a tri-gate FinFET. The inserted dielectric layers in the i-FinFET design allow to minimize the parasitic Gate-to-Source/Drain capacitance compared to GAA Nanowire-FET while leveraging fringing electric fields in the inserted dielectric layers to mitigate the loss of gate control over the sectioned channel region. The cavity used for the inserted-oxide in-between channel sections can also be thinner that the inserted dielectric/metal/dielectric layers in a comparable gate all around (GAA) field effect transistor (FET).

While the inserted-oxide architecture is relevant for narrow channel devices, such as FinFETs, the benefits are incompatible with wide sheet devices since the spatial extension of the fringing electric field is insufficient to reach the inner portion of the wider channels. This limitation leads to a complete loss of electrostatic control over the inner portion of the wider channels.

The hybrid inserted-oxide gate-all-around device with channel clusters (iGAA-FET) that are described in the present disclosure can provide hybrid and indirect gate control over the full width of stacked semiconductor channels, i.e., wide channels, to ensure full channel depletion. Each channel can be identical in electrostatic configuration. This can enable a stacked full depleted semiconductor on insulator (Stacked-FDSOI) type device. In addition, the total height of the stacked channels in iGAA-FET devices can be reduced compared to the equivalent GAA Nanosheet-FET devices leading to a reduction of the Parasitic Gate-to-Source/Drain capacitance.

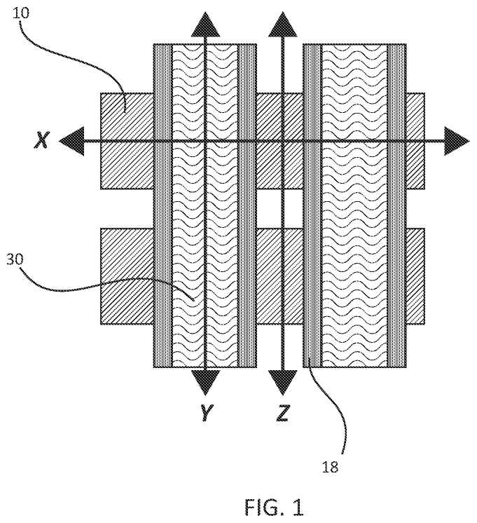

For example, for a nanosheet stack height for a GAA type gate structure equivalent in dimension to an existing device type not including the channel clusters of the hybrid inserted oxide gate all around device with channel clusters (iGAA-FET), assuming thin 4 nm to 5 nm semiconductor sheets, and effective fringing field effects through the inserted oxide, the hybrid inserted oxide gate all around device of the present disclosure can provide similar effective drive current (Ieff) to GAA field effect transistors, i.e., not including inserted oxide; and the hybrid inserted oxide gate all around device of the present disclosure can also reduce effective capacitance (Ceff). Overall, the hybrid inserted oxide gate all around device of the present disclosure can deliver improved drive current (Ieff) and reduced effective capacitance (Ieff/Ceff). The structures of the present disclosure are now described with reference to FIGS. 1-7.

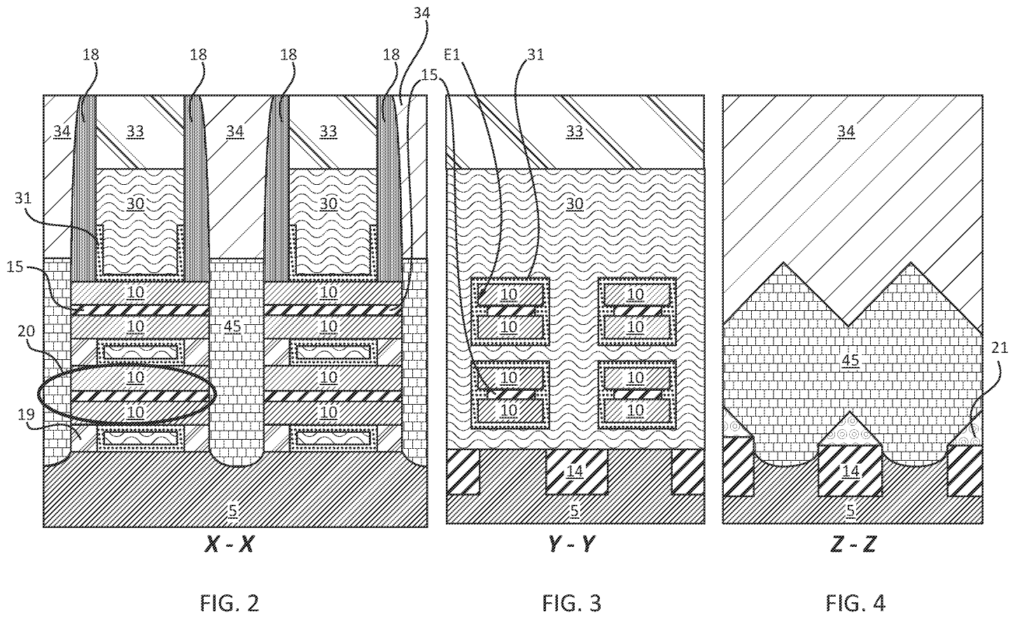

FIG. 1 is a top down view illustrating hybrid inserted dielectric gate all around devices with channel clusters. FIGS. 2-4 are side cross-sectional view of one embodiment of hybrid inserted-dielectric gate all around (GAA) field effect transistor (FET). A “field effect transistor” has three terminals, i.e., gate structure, source region and drain region. As used herein, the term “drain” means a doped region in semiconductor device located at the end of the channel region, in which carriers are flowing out of the transistor through the drain. The term “source” is a doped region in the semiconductor device, in which majority carriers are flowing into the channel region.

In one embodiment, the semiconductor device described herein includes a channel region of stacked semiconductor layers arranged in clusters 20. Each cluster 20 includes a pair of semiconductor sheets 10 with a dielectric material 15 present therebetween. The semiconductor device further includes a gate structure 30 encapsulating the channel region of stacked semiconductor layers 10 arranged in clusters 20. In some embodiments, a portion of the gate structure 30 is present between the clusters 20. Source and drain regions 45 are present on opposing sides of the channel region.

The channel of the device depicted in FIGS. 2-4 is composed of clusters 20 that include stacked semiconductor sheets 10 for channel regions. In one embodiment, a semiconductor device is provided including at least one pair of stacked semiconductor sheets 10 for channel regions. Each of pair of stacked semiconductor sheets 10 has an inserted dielectric 15 present between the semiconductor sheets 15. In this example, each cluster 20 includes two semiconductor sheets 15 having a inserted dielectric 15, e.g., inserted oxide, such as silicon oxide (SiO₂), that is present therebetween. As illustrated in FIGS. 2 and 3, the inserted dielectric 15 is present in direct contact with the upper surface of the lower semiconductor sheet 10 and is in direct contact with the lower surface of the upper semiconductor sheet 10 for each cluster. Although FIGS. 2 and 3 illustrate an embodiment including four clusters 20, the present disclosure is not limited to only this embodiment.

Any number of clusters 20 may be present in the gate structure. For examples, stacks of 3 and 4 clusters are suitable for the channel regions of the devices described herein. Further, the clusters may include more than just to sheets of semiconductor material 10. For example, a cluster could include three sheets of semiconductor material and two inserted dielectrics, in which each inserted dielectric present between two sheets of semiconductor material.

FIG. 3 illustrates how the embodiment described with reference to FIGS. 1-4 includes an inserted dielectric 15, e.g., inserted oxide, such as silicon oxide (SiO₂), does not extend to an edge E1 of semiconductor sheets 10. The edges E1 may be at the front and back surfaces of the semiconductor sheet 10 for the channel, which are viewed in the cross-section that sections the channel as illustrated in FIG. 3, i.e., across the channel. The inserted edge of the inserted dielectric 10 may be offset from the edges of the semiconductor sheets 10, which provides a divot type space between the sheets 10 having the inserted dielectric 15 that is present therebetween.

Referring to FIGS. 2 and 3, a gate structure 30 is provided encapsulating each pair stacked semiconductor sheets 10. The gate structure 30 is in directed contact with a lower surface of the a lower semiconductor sheet 10 in a second pair of stacked semiconductor sheets, and is in direct contact with an upper surface of an upper semiconductor sheet 10 in a first pair of semiconductor sheets.

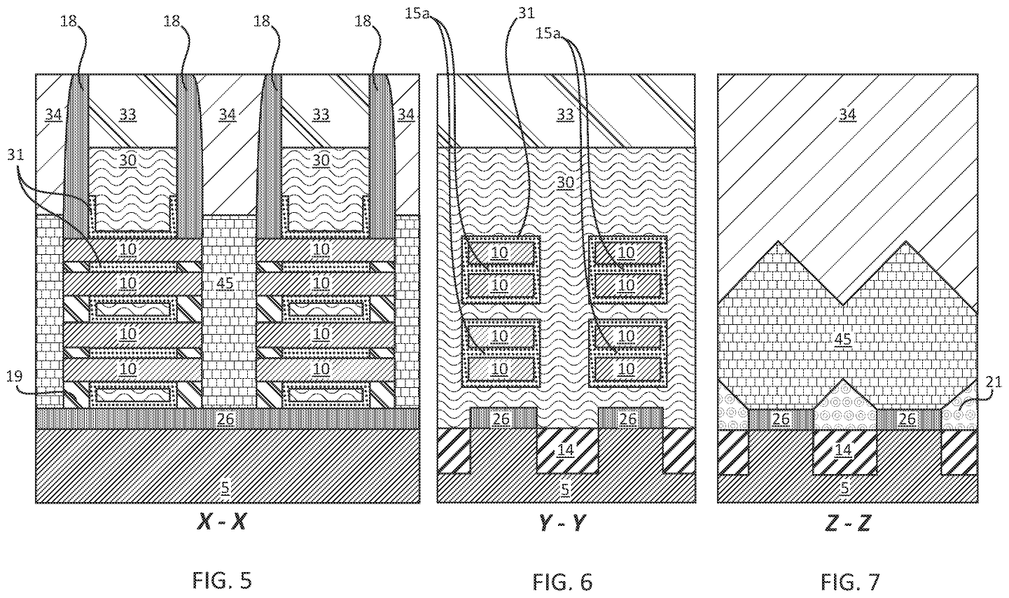

FIGS. 1 and 5-7 illustrate another embodiment of a hybrid inserted dielectric gate all around (GAA) device is provided with channel clusters 20. In the embodiments depicted in FIGS. 5-7, the inserted dielectric 15a may be provided by a gate dielectric 31 that is deposited to fill the space between at least two pairs of the stacked semiconductor layers 10 that provide the channel region. The dielectric material of the gate dielectric 31 is not present in the space separating the pairs of stacked semiconductor layers 10.

Referring to FIGS. 1 and 5-7, in one embodiment, a semiconductor device is provided including at least one pair of stacked semiconductor sheets 10 for channel regions. Each pair of stacked semiconductor sheets 10 has the space between them filled with a dielectric material 15a of the gate dielectric 31 for a gate structure 30 to the device. In this embodiment, the gate dielectric 31 of the wrap around, i.e., gate all around (GAA), gate structure 30, is present on the exterior of each of the semiconductor sheets. In this embodiment, the spacing between semiconductor sheets 10 provides that for some clusters 20 of semiconductor sheets, the thickness of the gate dielectric 31 fills the space between the clustered semiconductor sheets 10, which provides an inserted dielectric 15a, i.e., an inserted oxide.

Still referring to FIGS. 5-6, the semiconductor device further includes a gate structure 30 that encapsulates each pair of stacked semiconductor sheets 10 that provides a channel cluster 20. The gate structure 30 includes a gate electrode 32 for the gate dielectric 31 that is present between the first and second pair of stacked semiconductor sheets 10.

The gate structure 30 described with reference to FIGS. 1-7 provides that each channel, i.e., channel cluster 20, can have an identical electrostatic configuration. In some embodiments, the structures illustrated in FIGS. 1-8 provide a type of stacked fully depleted semiconductor on insulator (SOI) device.

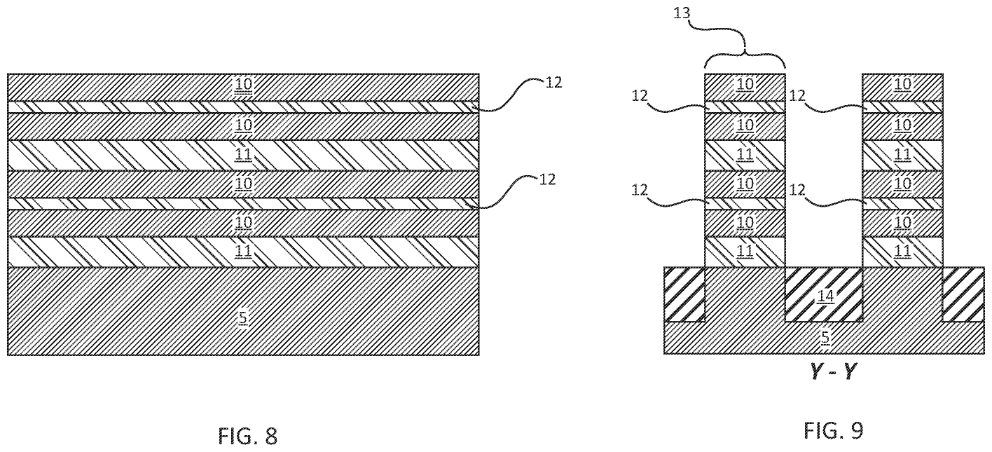

FIGS. 8-20 describe one embodiment of a method for forming the semiconductor device including the hybrid inserted dielectric, e.g., inserted oxide, such as silicon oxide (SiO₂), gate all around (GAA) device with channel clusters, as described above with reference to FIGS. 1-4.

FIG. 8 illustrates one embodiment of a material stack of epitaxially grown semiconductor materials that can be used as the initial structure for a process for forming the device depicted in FIGS. 1-4.

The materials selected for the stack are selected for their etch selectivity. As used herein, the term “selective” in reference to a material removal process denotes that the rate of material removal for a first material is greater than the rate of removal for at least another material of the structure to which the material removal process is being applied. For example, in one embodiment, a selective etch may include an etch chemistry that removes a first material selectively to a second material by a ratio of 10:1 or greater, e.g., 100:1 or greater, or 1000:1 or greater.

One composition, i.e., a first composition, is selected for the semiconductor sheets 10. A second composition semiconductor layer 11 is selected for the replacement gate process. A third composition semiconductor layer 12 is selected for removal in positioning of the inserted dielectric 15. The third composition semiconductor layer 12 is selected to be selective to the first and second composition semiconductor layer 11, while the second composition semiconductor layer 11 is selected to be selective to the first composition that provide the semiconductor sheets 10.

The supporting substrate 5 may be composed of a type IV semiconductor material, such as silicon. In one example, the supporting substrate 5 may be silicon having a <111> crystal orientation.

The first epitaxial layer to be deposited atop the supporting substrate 5 is a second composition semiconductor layer 11. As noted, this layer has a composition that is selected to be removed as part of the replacement gate process flow selectively to the layers that provide the semiconductor sheets 10. In some embodiments, the semiconductor composition may include silicon and germanium, in which the germanium content is selected to provide the aforementioned etch selectivity. For example, the second composition semiconductor layer 11 may be composed of silicon germanium (SiGe), in which the germanium content is equal to 25%. It is noted that this provides only one example of silicon germanium for the second composition semiconductor layer 11. In other embodiments, the germanium content may range from 15% to 35%.

The thickness of the first epitaxial layer that provides the first of the second composition semiconductor layers 11 may be selected so that the gate electrode of the subsequently formed functional gate structure 30 can fill the space between the bottom surface of the lowest semiconductor sheet 10 of the lowest channel cluster and the upper surface of the supporting substrate 5. In one example, the thickness of the first of the second composition semiconductor layers 11 is 12 nm. However, other embodiments have also been contemplated. For example, The channel regions provided by the semiconductor sheets can be greater than 4 nm in thickness, and the suspension space provided by the second composition semiconductor layers 11 may have a dimension greater than 8 nm.

Still referring to FIG. 8, a first composition semiconductor layer may then be deposited for a lower semiconductor sheet 10 for a channel cluster 20 of the device. As noted, the composition for the semiconductor sheets 10 can be selected so that the second composition semiconductor layers 11 and third composition semiconductor layers 12 can be removed without removing the material used for the semiconductor sheets 10 in the process sequences of the replacement gate process, and the sequence for forming the inserted dielectric 15.

In one example, the first composition semiconductor layer for the semiconductor sheet 10 may be composed of silicon (Si), e.g., 100 wt. % silicon (Si). The thickness of the first composition layer that provides the semiconductor sheets 10 may be on the order of 5 nm. However, any thickness is suitable so long as it can function as a channel of a device, and can withstand the etch processes of the replacement gate process and the processes for forming the inserted dielectric 15.

A semiconductor layer having a composition of the third composition semiconductor layer 12 is deposited atop the first composition semiconductor layer for the semiconductor sheets. The third composition semiconductor layer has a composition can be removed without substantially damaging the semiconductor layers that provide the semiconductor sheets for the channel or the second composition semiconductor layer 11 that is removed during the subsequence replacement gate process. In one embodiment, the semiconductor layer having a composition of the third composition semiconductor layer 12 is composed of silicon germanium, in which the germanium content is adjusted for the aforementioned etch selectivity conditions. For example, the third composition semiconductor layer 12 may be composed of silicon germanium (SiGe) having a germanium concentration of 60 wt. %. However, similar to the other materials of the semiconductor stack, other compositions have been contemplated. For example, the germanium content of the silicon germanium (SiGe) layer may range from 45 wt. % to 70 wt. %. The thickness of the third composition semiconductor layer 12 may be less than 5 nm. For example, the thickness of the third composition semiconductor layer 12 may be equal to 3 nm.

Still referring to FIG. 8, another first composition semiconductor layer may then be deposited for the semiconductor sheets that provides the upper sheet for a channel clusters of the device. As noted, the composition for the semiconductor sheets 10 can be selected so that the second composition semiconductor layers 12 and third composition semiconductor layers 12 can be removed without removing the material used for the semiconductor sheets 10 in the process sequences of the replacement gate process and the sequence for forming the inserted dielectric 15. The first composition semiconductor layer may be deposited atop the third composition semiconductor layer 12.

In one example, the first composition semiconductor layer for the semiconductor sheet 10 may be composed of silicon (Si), e.g., 100 wt. % silicon (Si). The thickness of the first composition layer that provides the semiconductor sheets 10 may be on the order of 5 nm. However, any thickness is suitable so long as it can function as a channel of a device, and can withstand the etch processes of the replacement gate process and the processes for forming the inserted dielectric 15.

The sequence of the second composition semiconductor layer 11, the first composition semiconductor layer for the lower semiconductor sheet 10, the third composition semiconductor layer 12 and the first composition semiconductor layer for the upper sheet 10 is a sequence for providing a single cluster 20 of semiconductor sheets 10 and inserted dielectric 15. In the embodiment depicted in FIG. 8, the process sequence is repeated to provide two rows of two channel clusters in a stack. It is noted that this illustrates only one embodiment of the present disclosure, and any number of channel clusters may be utilized.

As noted, each of the semiconductor material layers in the stack depicted in FIG. 8 is an epitaxial semiconductor material formed using epitaxial deposition. The term “epitaxial semiconductor material” denotes a semiconductor material that has been formed using an epitaxial deposition or growth process. “Epitaxial growth and/or deposition” means the growth of a semiconductor material on a deposition surface of a semiconductor material, in which the semiconductor material being grown has substantially the same crystalline characteristics as the semiconductor material of the deposition surface. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation. In some examples, the epitaxial deposition process may be provided using chemical vapor deposition (CVD).

FIG. 9 illustrates one embodiment of forming nanosheet stack structures 13 (in some examples having a geometry with height, width and length dimensions for the stack that are similar to that of a fin structure) from the stack illustrated in FIG. 88. FIG. 9 is a side cross-sectional view across the channel along section line Y-Y of FIG. 1.

In some embodiments, the nanosheet stack structures 13 may be formed from the stack using photolithography and etch processes. Specifically, in one example, a photoresist mask is formed overlying the portions of the stack which provides the nanosheet stack structures 13. The exposed portions of the semiconductor layer that provides the nanosheet stack structures 13 that are not protected by the photoresist mask are removed using an etch process, .e.g., anisotropic etch process. To provide the photoresist mask, a photoresist layer is first positioned on the semiconductor material that provides the nanosheet stack structures 13. The photoresist layer may be provided by a blanket layer of photoresist material that is formed utilizing a deposition process such as, e.g., spin-on coating.

The blanket layer of photoresist material is then patterned to provide the photoresist mask utilizing a lithographic process that may include exposing the photoresist material to a pattern of radiation and developing the exposed photoresist material utilizing a resist developer. Following the formation of the photoresist mask, an etching process may remove the unprotected portions of the semiconductor layers in the stack. The etch process may be an anisotropic process, such as reactive ion etch (RIE).

FIG. 9 also depicts forming isolation regions 14, e.g., shallow trench isolation (STI) regions. The isolation regions 14 are formed within the supporting substrate 5 by forming a trench between the nanosheet stack structures 13, and then filling the trench with a deposited dielectric material.

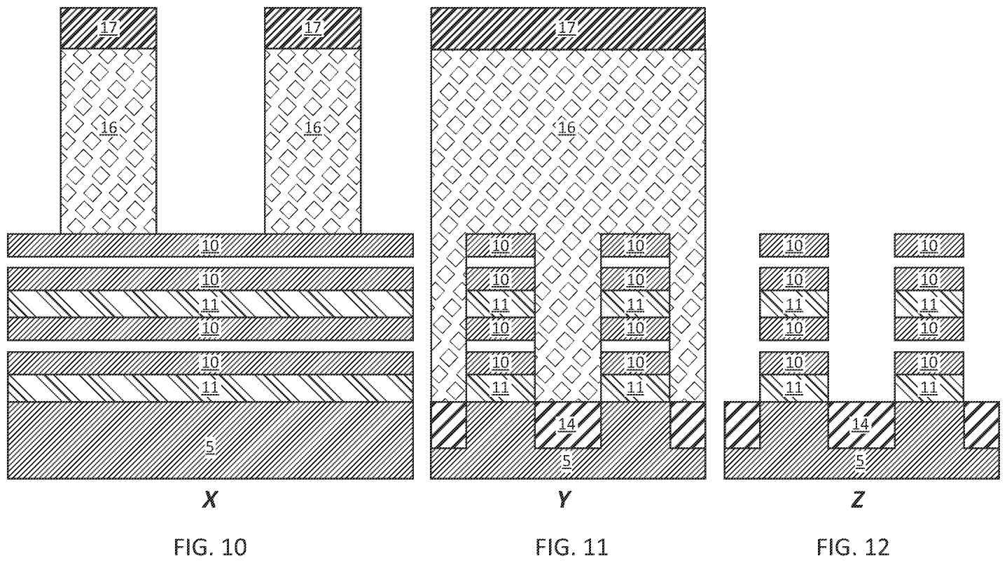

FIGS. 10-12 illustrate one embodiment of forming a sacrificial gate structure 16 on the nanosheet stack structures 13 depicted in FIG. 9, and removing the third composition semiconductor layer 12. The sacrificial gate structure 16 may be composed of amorphous silicon or polysilicon silicon. The sacrificial gate 16 is formed by depositing a material layer for the sacrificial gate electrode, forming a hardmask 17 atop the material layer for the sacrificial gate electrode that is patterned corresponding to the desired sacrificial gate 16 geometry; and then etching the material layer for the sacrificial gate electrode using the hardmask 17. The etch process may be anisotropic. The etch process may be selective to the upper surface of the semiconductor layer stack that provides the semiconductor sheets 10 for the channel clusters.

FIGS. 10-12 also depict removing the third composition semiconductor material layer 12 of the semiconductor stack. The third composition semiconductor material layer 12 provides the location of the subsequently formed inserted dielectric, e.g., inserted oxide, and has a composition that allows for removal of the layer selectively to the first composition semiconductor material layers for the semiconductor sheets 10 and the second composition semiconductor material layers 12 that are removed during the replacement gate process. The etch process may be a non-directional etch, such as a plasma etch or wet chemical etch process. In some embodiments, the etch process removes silicon germanium (SiGe) composition of the third composition semiconductor layer 12 having a germanium (Ge) concentration of 60 wt. % selectively to the silicon, e.g., 100 wt. % silicon (Si), composition of the semiconductor sheets 10, and the silicon germanium (SiGe) composition of the second composition semiconductor layer 11 having a germanium concentration of 25 wt. %.

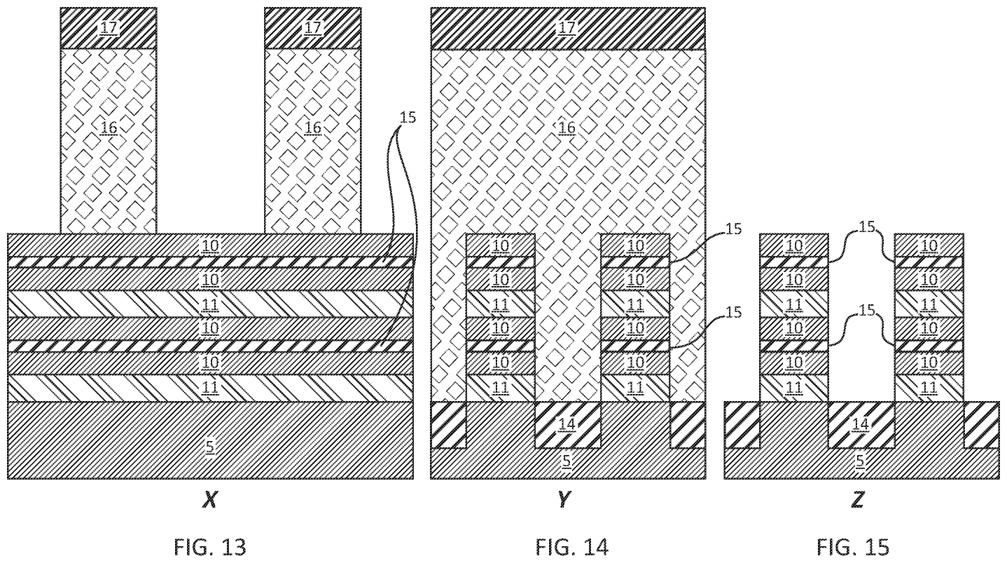

FIGS. 13-15 illustrate one embodiment of forming the inserted dielectric layer 15. In some embodiments, the inserted dielectric layer 15 may be composed of an oxide. For example, the inserted dielectric layer may be formed of deposited silicon oxide (SiO₂) or a metal oxide, such as aluminum oxide (AlOx (e.g., Al₂O₃). In some embodiments, the inserted dielectric layer 15 may be a high-k dielectric, such as hafnium oxide (HfO₂), In some embodiments, the inserted dielectric layer 15 may be deposited using a conformal deposition process. For example, the inserted dielectric layer 15 may be formed using chemical vapor deposition methods, such as metal organic chemical vapor deposition or plasma enhanced chemical vapor deposition. In one examples, the inserted dielectric layer 15 may also be formed using atomic layer deposition (ALD). The thickness of the inserted dielectric layer 15 may be nanoscale, e.g., being less than 5 nm in thickness.

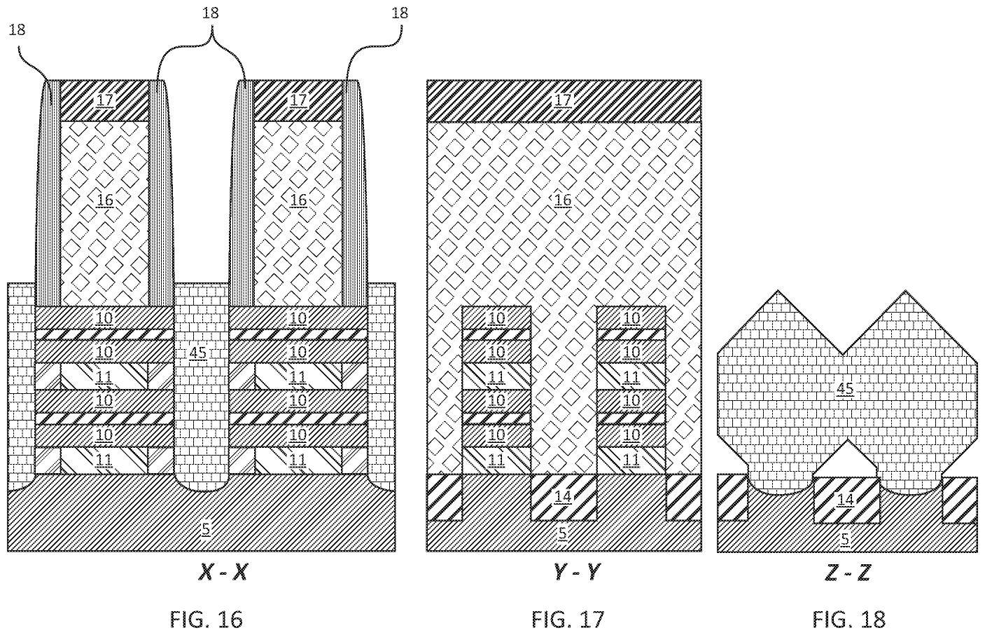

FIGS. 16-18 illustrate one embodiment of forming a spacer 18 on the sidewall of the sacrificial gate structure 16, recessing exposed portions of the semiconductor stack between the assembly of the spacer 18 and the sacrificial gate structures 16, then forming an inner spacer 19 within the semiconductor stack, and then forming the epitaxial semiconductor material for the source and drain regions 45.

In some embodiments, spacers 18 are formed on the sidewalls of the sacrificial gate structures 16. The spacer material may comprise a dielectric, such as a nitride, oxide, oxynitride, or a combination thereof. In some embodiments, the spacer material may be a low-k dielectric material, such as SiOC, SiON, SiOCN, SiBCN and combinations thereof. The spacers of a gate structure can be formed using a conformal deposition process, such as plasma enhanced chemical vapor deposition (PECVD) or atomic layer deposition (ALD), that is followed by an etch back process, such as reactive ion etching (RIE).

FIGS. 16-18 also depict one embodiment of recessing the nanosheet stack structures 13. Recessing the nanosheet stack structures may include an anisotropic etch process, such as reactive ion etching, that employs the sacrificial gate 16 and spacers 18 as an etch mask. As illustrated in FIGS. 16-18, a portion of the nanosheet stack structures remain in the channel regions of the device, whereas an entirety of the nanosheet stack structures has been removed from the portions of the structure in which the source and drain regions 45 are subsequently formed.

FIGS. 16-18 also illustrate one embodiment of inner spacer 19 formation. The inner spacer 19 supports the layers of the stack, i.e., the semiconductor sheets 10 and the inserted dielectric 15 that provides the channel clusters 20, following removal of the second composition semiconductor layers 11 during the replacement gate process flow. Forming the inner spacer 19 may include selective indentation of second composition semiconductor layers 11; conformal deposition of a dielectric layer for providing the inner spacer 19, and an etchback process for removing at least a portion of the dielectric material for the inner spacer 19 that was not present in the indentation.

In some embodiments, the etch process for forming the indentation removes the second composition semiconductor layers 11 selectively to the semiconductor sheets 10 and inserted dielectric 15. The etch process for forming the indentation by removing the sidewall portions of the second composition semiconductor layers 11 may be an isotropic etch, such vapor phase etch, plasma etch or wet etch.

In a following process step, a conformal deposition is performed of a material layer for providing the inner spacer 19. To provide the conformal layer, the dielectric material layer for forming the inner spacer 19 may be deposited using atomic layer deposition (ALD) or plasma enhanced chemical vapor deposition (PECVD). The inner spacer may be formed of an oxide, nitride or oxynitride material. In some examples, the inner spacer 19 is composed of silicon nitride. In other examples, the inner spacer 19 is composed of silicon oxide. In some embodiments, the inner spacer material may be a low-k dielectric material, such as SiOC, SiON, SiOCN, SiBCN and combinations thereof.

It is noted that the conformally deposited material layer for the inner spacer 19 is not only formed in the indentation that is formed by removing the sidewall portions of the second composition semiconductor layers 12. The conformally deposited material for the inner spacer 19 is also formed on the sidewalls of the nanosheet stack structures and spacers 18. To remove the portions of the conformally deposited material layer for the inner spacer 19 that extend from the indentation, an etch back process is applied. The etch back process may be an isotropic etch. As opposed to an anisotropic etch, an isotropic etch is substantially non-directional. The etch back process may be a timed etch to ensure that the remaining portion of the conformally deposited material is only present in the indentation to provide the inner spacer 19.

FIGS. 16-18 also depict one embodiment of forming the source/drain epitaxy regions 45 from epitaxially grown semiconductor materials. In some embodiments, the epitaxial source and drain region portions 45 may be composed of a type IV semiconductor material, such as silicon (Si). The source and drain epitaxy regions 45 are grown on the exposed sidewalls of the semiconductor material of the nanosheet stack structures using an epitaxial growth or deposition process.

The source/drain epitaxy regions 45 may be composed of silicon (Si) that is p-type doped or n-type doped. The dopant, i.e., p-type or n-type dopant, may be introduced to the source/drain epitaxy regions 45 using insitu doping. The term “in situ” denotes that the dopant, e.g., n-type or p-type dopant, is introduced to the base semiconductor material, e.g., silicon or silicon germanium, during the formation of the base material. For example, an in situ doped epitaxial semiconductor material may introduce n-type or p-type dopants to the material being formed during the epitaxial deposition process that includes n-type or p-type source gasses.

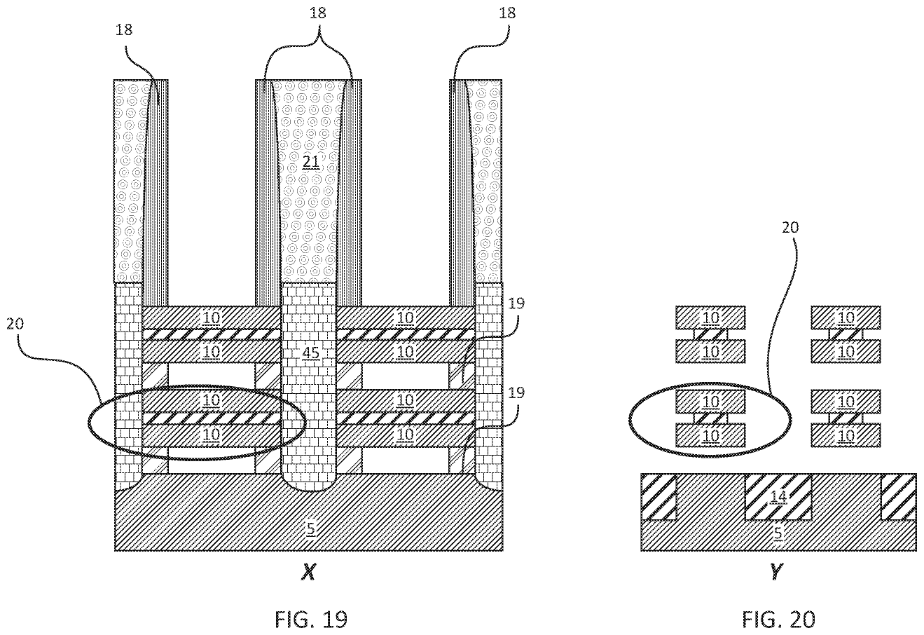

FIGS. 19 and 20 depict removing the sacrificial gate structure 16 and removing the second composition semiconductor layers 11. FIGS. 19 and 20 also depict one embodiment of forming an inter-level dielectric layer 21 having an upper surface that is coplanar with the upper surface of the sacrificial gate structure 16 (more specifically, with an upper surface of a hardmask 17 atop the sacrificial gate structure 16). The intralevel dielectric layer 21 may be selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The interlevel dielectric layer 37 may be deposited by chemical vapor deposition (CVD), physical vapor deposition (PVD), spin on deposition, deposition from solution or a combination thereof. Following deposition, the upper surface of the intralevel dielectric layer 21 may be planarized until coplanar with the upper surface of the sacrificial gate structure 16 (more specifically, with an upper surface of a hardmask 17 atop the sacrificial gate structure 16). The planarization process may be provided by chemical mechanical planarization.

FIGS. 19-20 depict one embodiment of removing the sacrificial gate structure 16, and removing the second composition semiconductor layer 11. The sacrificial gate structure 16 and the second composition semiconductor layer 11 may be removed by selective etching processes. The etch chemistry may be selected to remove the amorphous silicon of the sacrificial gate structure 16, and to remove the second composition semiconductor layer 11 selectively to the semiconductor sheets 10. In some embodiments, the sacrificial gate structure 16 and the second composition semiconductor layer 11 may be removed by an isotropic etch, such as gas etching, plasma etching or a wet etch. Removing the second composition semiconductor layer 11 may expose the exterior sidewalls of the channel clusters 20, in which each channel cluster 20 includes two semiconductor sheets 10 having an inserted dielectric layer 15 present therebetween.

In some embodiments, the etch processes for removing at least one of the sacrificial gate structure 16 and the second composition semiconductor layer 11 may cause a lateral pullback of the material for the inserted dielectric 15. The notch formed by the lateral pullback of the inserted dielectric may be filled with gate dielectric of the subsequently formed functional gate structure 30.

Referring back to FIGS. 2-4, the process may continue with forming a functional gate structure 30 in the space that is opened by removing the sacrificial gate structure 16 and the third composition semiconductor layer 12. The functional gate structure 30 is formed wrapping around the channel clusters 20. The “functional gate structure” operates to switch the semiconductor device from an “on” to “off” state, and vice versa. The functional gate structure 30 includes at least one functional gate dielectric 31 and at least one functional gate electrode 32.

The functional gate dielectric 31 may be a high-k dielectric material layer that is formed in direct contact with the channel clusters 20 provided by the semiconductor sheets 10 and inserted dielectrics 15. High-k dielectric materials may have a dielectric constant greater than silicon oxide (SiO₂). For example, high-k dielectrics having a dielectric constant greater than 4.0 at room temperature, e.g., 20° C. to 25° C. and atmospheric pressure, e.g., 1 atm. In one example, the gate dielectric can be hafnium oxide (HfO₂). In one embodiment, the high-k dielectric material for the functional gate dielectric 41 is composed of a high-k oxide such as, for example, HfO₂, ZrO₂, Al₂O₃, TiO₂, La₂O₃, SrTiO₃, LaAlO₃, Y₂O₃ and mixtures thereof. Other examples of high-k dielectric materials may include hafnium silicate, hafnium silicon oxynitride or combinations thereof.

In one embodiment, the functional gate dielectric 31 may be deposited by chemical vapor deposition (CVD). Variations of CVD processes suitable for depositing the at least one gate dielectric layer include, but are not limited to, atmospheric pressure chemical vapor deposition (APCVD), low pressure chemical vapor deposition (LPCVD), plasma enhanced chemical vapor deposition (PECVD), metal organic chemical vapor deposition (MOCVD), atomic layer deposition (ALD), and combinations thereof. In other embodiments, the functional gate dielectric 41 is deposited by atomic layer deposition.

The functional gate dielectric 31 can be deposited having a conformal thickness. In one embodiment, the thickness of the high-k dielectric material layer is greater than 0.8 nm. More typically, the high-k dielectric material layer has a thickness ranging from about 1.0 nm to about 6.0 nm.

In some embodiments, the functional gate dielectric 31 pinches off the notch in the channel cluster 20 created by the lateral pullback of the inserted dielectric layer 15 during etch processes.

The method may continue with depositing a functional gate electrode 32, e.g., a metal gate electrode, in the gate opening atop the functional gate dielectric 31. In some embodiments, a metal gate stack is formed by first depositing work function metals (WFM) such as TiN, TiC, and TiCAl to calibrate the threshold voltage of the device. This layer is followed by the deposition of the gate metal electrode to complete the metal fill of the gate. In some examples, the gate metal electrod may be composed of tungsten (W). In some embodiments, a deposited metal provides the functional gate electrode 32 of the functional gate structure 30. The material for the functional gate electrode 32 may be formed using a deposition process. The metal may fill the gate opening. In some embodiments, the metal is formed using a physical vapor deposition (PVD) process, such as sputtering. Examples of sputtering apparatus that may be suitable for depositing the at least one gate conductor include DC diode type systems, radio frequency (RF) sputtering, magnetron sputtering, atomic layer deposition, and ionized metal plasma (IMP) sputtering. In some embodiments, a dielectric cap structure 33 may be formed atop the functional gate electrode 32.

In some embodiments, portions of the interlevel dielectric layer may be patterned and etched to provide via holes to the source/drain epitaxy regions 24. Contacts 34 may be formed in the via holes.

The process sequence described with reference to FIGS. 8-20 provides one embodiment for a method for forming the semiconductor devices described above and depicted in FIGS. 1-4.

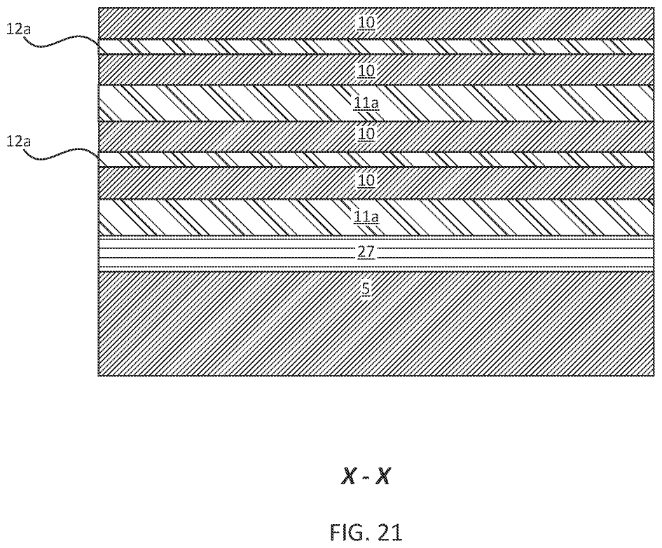

The embodiments depicted in FIGS. 1 and 5-7 are now described with reference to FIGS. 21-32. FIG. 21 illustrates embodiment of a material stack of epitaxially grown semiconductor materials that can be used as the initial structure for a process for forming the device depicted in FIGS. 1 and 5-7. The embodiment depicted in FIG. 21 is similar to the material stack depicted in FIG. 9 with the exception that the layers having compositions selected for integration of a bottom dielectric isolation (BDI) layer, and in the embodiments described with reference to FIGS. 1, 5-7 and 21-32, the inserted dielectric layer 15a is provided by a gate dielectric layer completely filling the space between two adjacently stacked semiconductor sheets 10.

In one example, the semiconductor material layer for the sacrificial BDI layer 27 may have a composition that can be removed selectively to the semiconductor sheets 10, as well as the sacrificial material layer that provides the location for the inserted dielectric layer 15a.

In addition to the semiconductor material layer for the sacrificial BDI layer 27, the material stack depicted in FIG. 21 also includes a first composition semiconductor layers for the semiconductor sheets 10, second composition semiconductor layers 11a that are removed as elements of the replacement gate process, and third composition semiconductor layers 12a that that provide the location of the inserted dielectric layer 15a. However, different from the embodiments described with reference to FIGS. 1-4 and 8-20, the second composition semiconductor layers 11a that are removed as elements of the replacement gate process, and third composition semiconductor layers 12a that that provide the location of the inserted dielectric layer 15a may have the same composition, because they are removed by the same etch process.

In one example, the semiconductor material layer for the sacrificial BDI layer 27 is composed of silicon germanium, in which the germanium content is on the order of 60 wt. %. In one example, the composition of the semiconductor sheets 10 is silicon (Si), e.g., 100 wt. % silicon (Si). In one example, the second composition semiconductor layer 11a that provides the sacrificial material layer for the replacement gate process, and the third composition semiconductor layer 12a that provides the position of the inserted dielectric layer 15a are both silicon germanium, in which the germanium (Ge) content is equal to approximately 25 wt. %. It is noted that this is only one example of a material stack that can be implemented in accordance with the methods and structures described herein. Similar to the embodiments described with reference to FIGS. 1-4 and 8-20, the material layers may be deposited by epitaxial deposition methods. The thickness of the third composition semiconductor layer is selected to provide that the space between adjacently stacked semiconductor sheets 10 is filled by the material of the gate dielectric 31 during the deposition processes for forming the functional gate structure 30.

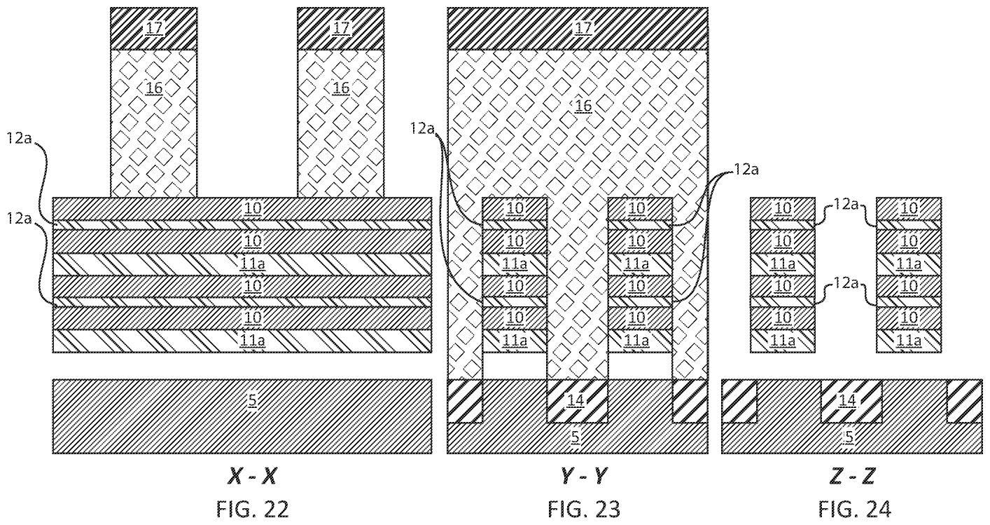

FIGS. 22-24 illustrate one embodiment of forming a sacrificial gate structure 16 on the nanosheet stack structures formed from the stack depicted in FIG. 22, and removing the sacrificial semiconductor layer 27 for forming the bottom dielectric isolation (BDI) layer. The sacrificial gate structure 16 is formed similar to the sacrificial gate structure 16 that is depicted in FIGS. 10-12. Therefore, the description for the sacrificial gate structure 16 from FIGS. 10-12 is applicable for the sacrificial gate structure 16 that is depicted in FIGS. 22-24.

FIGS. 22-24 also illustrate removing the sacrificial BDI layer 27. The sacrificial BDI layer 26 is removed by an etch process that is selective to the remainder of the material layers in the stack. The etch process for forming the buried cavity by removing the sidewall portions of the second composition semiconductor layers 12 may be an isotropic etch, such as vapor phase etch, plasma gas etch or wet etch.

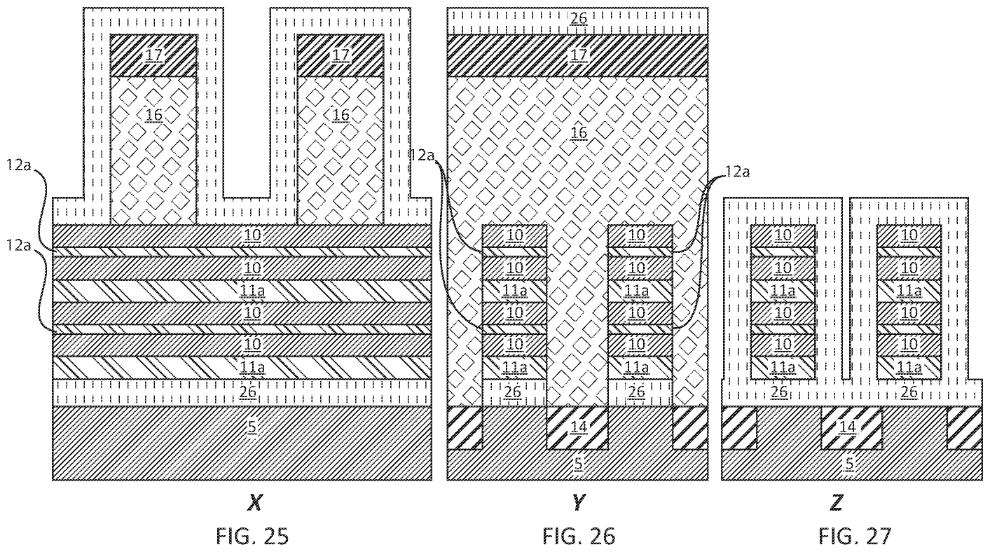

FIGS. 25-27 illustrate one embodiment of forming the bottom dielectric isolation layer 26 simultaneously with gate sidewall spacers on the sacrificial gate structure 16. More specifically, the material layer for the spacer is formed on the sidewall of the sacrificial gate structure 16, wherein the material layer for the gate sidewall spacer also fills the void created by removing the material of the sacrificial BDI layer 27. Filling that void with dielectric material provides the bottom dielectric isolation layer 26.

The spacer material that also provides the bottom dielectric isolation layer 22 may comprise a dielectric, such as a nitride, oxide, oxynitride, or a combination thereof. In some embodiments, the spacer material may be a low-k dielectric material, such as SiOC, SiON, SiOCN, SiBCN and combinations thereof. The spacers of a gate structure can be formed using a conformal deposition process, such as plasma enhanced chemical vapor deposition (PECVD) or atomic layer deposition (ALD), that is followed by an etch back process, such as reactive ion etching (RIE).

Following deposition of the spacer material, the nanosheet stack structures may be recessed using an anisotropic etch process, such as reactive ion etching. Prior to recessing the nanosheet stack structures, an etch back process is applied to the conformal material layer that provides both the material for the gate sidewall spacers and the bottom dielectric isolation layer 26. The etch back process provides the gate sidewall spacer geometry from the conformally deposited layer. The etch process for recessing the nanosheet stack structures employs the sacrificial gate 16 and spacers 18 as an etch mask. The etch process for recessing the nanosheet stack structures can terminate on the bottom dielectric isolation layer 26.

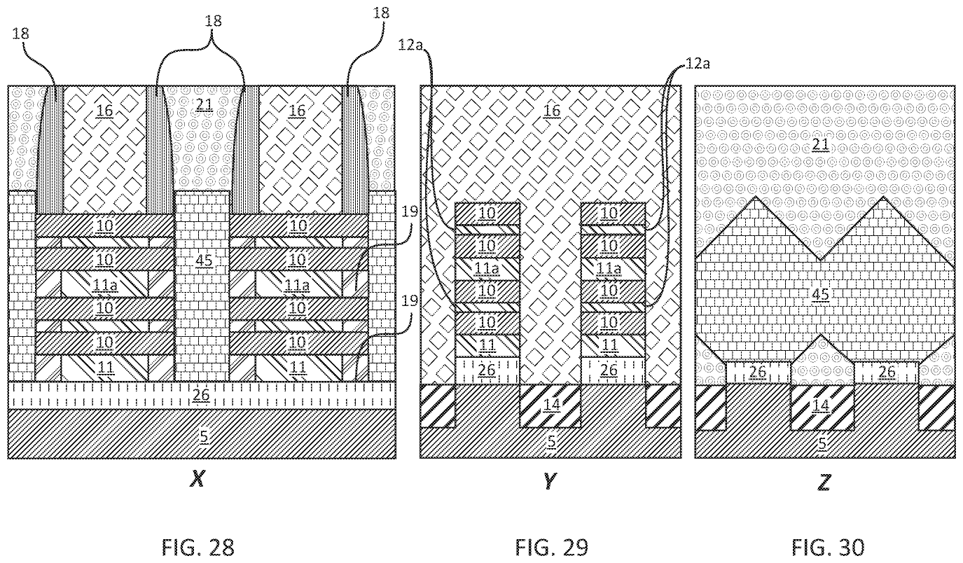

Referring to FIGS. 28-30, in a subsequent sequence, the source/drain epitaxy material 45 may be formed followed by the deposition of an interlevel dielectric layer 21 and a planarization process. The source/drain epitaxy material 45 depicted in FIGS. 28-30 is similar to the source/drain epitaxy regions that are depicted in FIGS. 16-18. Therefore, the description of the source/drain epitaxy regions 45 that are depicted in FIGS. 28-30 are applicable for the source/drain epitaxy regions that are illustrated in FIGS. 16-18. Further, the description of the interlevel dielectric layer 21 from FIGs. FIGS. 19 and 20 is suitable for describing the interlevel dielectric layer 21 that is depicted in FIGS. 28-30.

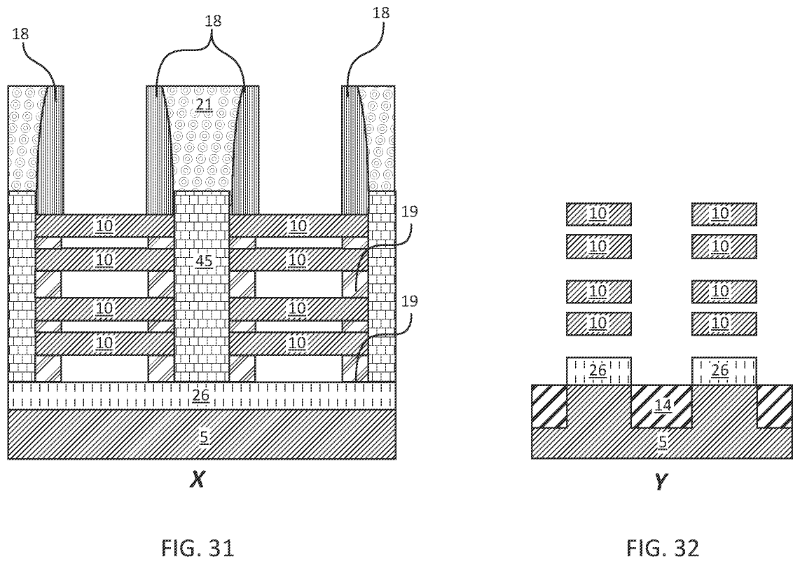

FIGS. 31 and 32 illustrate removing the sacrificial gate structure 16 and removing the second composition semiconductor layer 11a that provides the sacrificial material layer for the replacement gate process, and the third composition semiconductor layer 12a that provides the position of the inserted dielectric layer 15a. The sacrificial gate structure 16, the second composition semiconductor layer 11a, and the third composition semiconductor layer 12a may be removed by selective etching processes.

The etch chemistry may be selected to remove the amorphous silicon of the sacrificial gate structure 16, and to remove the second composition semiconductor layer 11a and third composition semiconductor layer 12a selectively to the semiconductor sheets 10. In some embodiments, the sacrificial gate structure 16, the second composition semiconductor layer 11a and the third composition semiconductor layer 12a may be removed by an isotropic etch, such as vapor phase etching, plasma etching or a wet etch.

FIGS. 34 and 35 depicts one embodiment of forming the gate dielectric 31 of a functional gate structure 30. The functional gate dielectric 31 is formed wrapping around the channel clusters 20. The thickness of the functional gate dielectric 31 is selected to provide that the material of the gate dielectric 31 fills the space between the adjacently stacked sheets 10 that provide a channel cluster 20 of two sheets 10 and an inserted dielectric 15 positioned therebetween, in which the inserted dielectric 15a is provided by the material of the gate dielectric 31.

The functional gate dielectric 31 may be a high-k dielectric material layer that is formed in direct contact with the channel clusters 20 provided by the semiconductor sheets 10 and inserted dielectrics 15. In one example, the gate dielectric 31 can be hafnium oxide (HfO₂). In one embodiment, the high-k dielectric material for the functional gate dielectric 41 is composed of a high-k oxide such as, for example, HfO₂, ZrO₂, Al₂O₃, TiO₂, La₂O₃, SrTiO₃, LaAlO₃, Y₂O₃ and mixtures thereof. Other examples of high-k dielectric materials may include hafnium silicate, hafnium silicon oxynitride or combinations thereof.

In one embodiment, the functional gate dielectric 31 may be deposited by chemical vapor deposition (CVD). Variations of CVD processes suitable for depositing the at least one gate dielectric layer include, but are not limited to, atmospheric pressure chemical vapor deposition (APCVD), low pressure chemical vapor deposition (LPCVD), plasma enhanced chemical vapor deposition (PECVD), metal organic chemical vapor deposition (MOCVD), atomic layer deposition (ALD), and combinations thereof. In other embodiments, the functional gate dielectric 41 is deposited by atomic layer deposition. The functional gate dielectric 31 can be deposited having a conformal thickness. In one embodiment, the thickness of the high-k dielectric material layer is greater than 0.8 nm. More typically, the high-k dielectric material layer has a thickness ranging from about 1.0 nm to about 6.0 nm.

The method may continue with depositing a functional gate electrode 32, e.g., a metal gate electrode, in the gate opening atop the functional gate dielectric 31, as illustrated in FIGS. 1 and 5-7. The functional gate electrode 32 depicted in FIGS. 1 and 5-7 is similar to the functional gate electrode 32 that has been described with reference to FIGS. 1-4. Similarly, contacts to the source and drain regions may be formed, as described with reference to FIGS. 1-4.

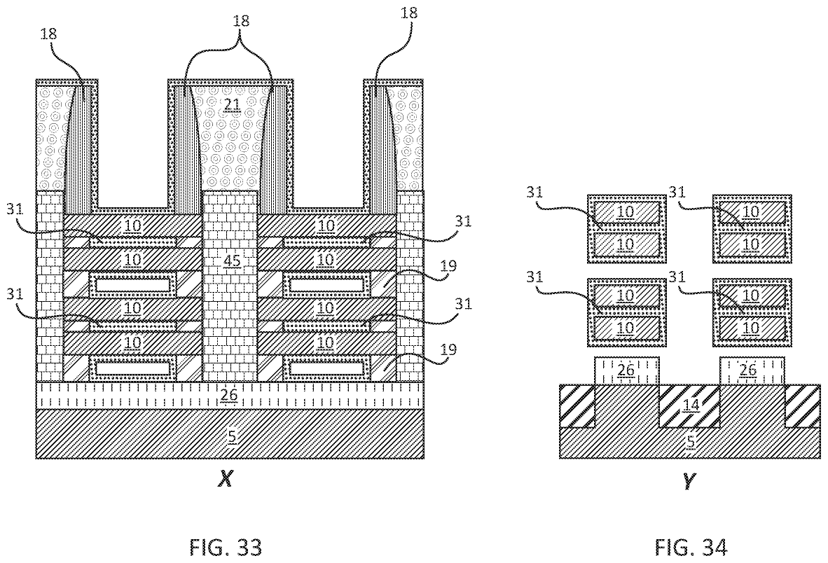

The methods and structures that have been described above with reference to FIGS. 1-34 may be employed in any electrical device. For example, the devices that are disclosed herein may be present within electrical devices that employ semiconductors that are present within integrated circuit chips. The integrated circuit chips including the disclosed interconnects may be integrated with other chips, discrete circuit elements, and/or other signal processing devices as part of either (a) an intermediate product, such as a motherboard, or (b) an end product. The end product can be any product that includes integrated circuit chips, including computer products or devices having a display, a keyboard or other input device, and a central processor.

Having described preferred embodiments of a methods and structures for a hybrid inserted dielectric gate all around device are disclosed herein, it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device comprising:
at least one of pair of stacked semiconductor sheets for channel regions, wherein the at least one pair of stacked semiconductor sheets has an inserted dielectric present between the semiconductor sheets; and
a gate structure encapsulating the at least one pair of stacked semiconductor sheets, wherein the gate structure is in directed contact with a lower surface of a lower semiconductor sheet in at least one pair of stacked semiconductor sheets, and is in direct contact with an upper surface of an upper semiconductor sheet in the at least one pair of semiconductor sheets.

2. The semiconductor device of claim 1, wherein the inserted dielectric does not extend to an edge of semiconductor sheets.

3. The semiconductor device of claim 1, wherein the at least one pair of stacked semiconductor sheets includes at least a first pair of semiconductor sheets and a second pair of semiconductor sheets, wherein the gate structure is in directed contact with a lower surface of a lower semiconductor sheet in the second pair of stacked semiconductor sheets, and is in direct contact with an upper surface of an upper semiconductor sheet in the first pair of semiconductor sheets.

4. The semiconductor device of claim 1, wherein the at least one pair of stacked semiconductor sheets having the one inserted dielectric is a channel cluster.

5. The semiconductor device of claim 14, wherein the gate structure includes a gate dielectric that wraps around an exterior surface of the channel cluster, and the channel structure includes a gate electrode in directed contact with the gate dielectric.

6. A semiconductor device comprising:
at least one of pair of stacked semiconductor sheets for a channel region; and
a gate structure including a gate dielectric and a gate electrode present on the channel region encapsulating each of the at least one pair of stacked semiconductor sheets, wherein the at least one pair of stacked semiconductor sheets has a space between the stacked semiconductor sheets filled with a dielectric material of the gate dielectric for the gate structure, and a portion of the gate electrode for the gate structure is present encapsulating an exterior of the at least one pair of stacked semiconductor sheets having the spaced between the stacked sheets filled with the dielectric material.

7. The semiconductor device of claim 6 further including a base dielectric isolation layer present between the at least one pair of stacked semiconductor sheets and a supporting substrate.

8. The semiconductor device of claim 6, wherein a channel cluster is provided by the at least one pair of stacked semiconductor sheets having the space between the stacked semiconductor sheets filled with the dielectric material of the gate dielectric, wherein a portion of the gate dielectric having a conformal thickness is present on exterior surfaces of the channel cluster.

9. The semiconductor device of claim 6, wherein the dielectric material of the gate dielectric for the gate structure is comprised of a high-k dielectric material.

10. A semiconductor device comprising:
a channel region of stacked semiconductor layers arranged in clusters, wherein each cluster includes a pair of the semiconductor sheets with a dielectric material present therebetween; a gate structure encapsulating the channel region of stacked semiconductor sheets arranged in clusters, wherein a portion of the gate structure is present between the clusters; and
source and drain regions present on opposing sides of the channel region.

11. The semiconductor device of claim 10, wherein the dielectric material that is present between the pair of semiconductor sheets has a different composition than a composition of the gate dielectric of the gate structure.

12. The semiconductor device of claim 11, wherein the dielectric material that is present between the pair of semiconductor sheets is laterally offset from an edge of the pair of semiconductor sheets, wherein a space created by the laterally offset dielectric of the clusters is filled with the gate dielectric.

13. The semiconductor device of claim 10, wherein the dielectric material that is present between the pair of semiconductor sheets has a same composition as a composition of the gate dielectric of the gate structure.

14. The semiconductor device of claim 13 further including a base dielectric isolation layer present between a first of the clusters in the channel and a supporting substrate.

15. A method of forming a semiconductor device comprising:
forming a material stack on a supporting substrate including a first composition of semiconductor layers for semiconductor sheets employed for channel regions, second composition semiconductor layers for a replacement gate process, and third composition semiconductor layers for positioning inserted dielectrics between two of said semiconductor sheets in a channel cluster;
forming a sacrificial gate structure on the material stack;
substituting an inserted dielectric for the third composition semiconductor layers;
forming source and drain epitaxial regions on opposing sides of the channel region;
removing the sacrificial gate structure and the second composition semiconductor layers, wherein removing the second composition semiconductor layers exposes at least one channel cluster including two semiconductor sheets having an inserted dielectric present therebetween; and
forming a functional gate structure on the at least one channel cluster, wherein the functional gate structure encapsulates the at least one channel cluster.

16. The method of claim 15, wherein the inserted dielectric does not extend to an edge of semiconductor sheets.

17. The method of claim 15, wherein the inserted dielectric is an oxide.

18. The method of claim 15, wherein the functional gate structure includes a gate dielectric that wraps around an exterior surface of the at least one channel cluster, and the functional gate structure includes a gate electrode in directed contact with the gate dielectric.

19. The method of claim 15, wherein the substituting of the inserted dielectric for the third composition semiconductor layers comprises a selective etch for removing the third composition semiconductor layers selectively to at least one of the first composition of the semiconductor layers for the semiconductor sheets and the second composition semiconductor layers.

20. The method of claim 19, wherein etch selectivity is provided by different germanium contents between the third composition semiconductor layer and at least one of the first composition of the semiconductor layers for the semiconductor sheets and the second composition semiconductor layers.

21. A method of forming a semiconductor device comprising:
providing a material stack on a supporting substrate including a first composition of semiconductor layers for semiconductor sheets employed for channel regions, and a second composition semiconductor layers for a replacement gate process and for positioning inserted dielectrics between two of said semiconductor sheets in at least one channel cluster;
forming a sacrificial gate structure on the material stack;
forming source and drain epitaxial regions on opposing sides of the channel region;
removing the sacrificial gate structure and the second composition semiconductor layers, wherein removing the second composition semiconductor layers exposes the at least one channel cluster each including two semiconductor sheets having an a space for inserted dielectric present therebetween; and
forming a gate dielectric of a functional gate structure on the at least one channel cluster, wherein the functional gate dielectric encapsulates an entirety of each of the at least one channel cluster and fills a space separating the at least two semiconductor sheets for the at least one channel cluster.

22. The method of claim 21 further comprising forming a gate electrode on the gate dielectric.

23. The method of claim 21 further including a base dielectric isolation layer present between a first of the at least one channel clusters and a supporting substrate.

24. The method of claim 21, wherein the dielectric material of the gate dielectric for the gate structure is comprised of a high-k dielectric material.

25. The method of claim 21, wherein etch selectivity for removing the second composition semiconductor layers is provided by different germanium contents between the second composition semiconductor layers and the first composition of the semiconductor layers for the semiconductor sheets.
